(19) United States
(12) Patent Application Publication
(10) Pub. No.: US 2005/0073009 A1
(43) Pub. Date: Apr. 7, 2005

(54) Semiconductor device

(76) Inventors: Kenji Kojima, Yokohama-shi (JP); Tatsuya Ohguro, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/865,999

(22) Filed: Jun. 14, 2004

(30) Foreign Application Priority Data
Oct. 6, 2003 (JP) 2003-347274

(51) Int. Cl. H01L 23/62

(52) U.S. Cl. 257/362

(57) ABSTRACT

A MOS transistor in a semiconductor device allows a surge current to flow between source and drain to protect main circuits, includes a first conductive type well formed in a semiconductor substrate and having a first impurity concentration. A source region as the source and a drain region as the drain are formed in the surface of the well to sandwich a channel region under a gate electrode which is provided above the well and is electrically connected to ground. The source region and the drain region have a second conductive type opposite to the first conductive type. One of them is electrically connected to ground. A first impurity diffusion region of the first conductive type is formed along the surfaces of the source and drain regions facing the channel region, and has a second impurity concentration higher than the first impurity concentration.

### CROSS-REFERENCE TO RELATED APPLICATIONS

This application is based upon and claims the benefit of priority from prior Japanese Patent Application No. 2003-347274, filed Oct. 6, 2003, the entire contents of which are incorporated herein by reference.

### BACKGROUND OF THE INVENTION

1. Field of the Invention

The present invention relates to a semiconductor device, and, more specifically, to an electrostatic protective circuit for an I/O section of a semiconductor device.

2. Description of the Related Art

An electrostatic protective circuit (electrostatic discharge [ESD] protective circuit) is known which protects elements in a semiconductor device such as an integrated circuit (IC). FIG. 21 shows a first conventional example using a GGNMOS as an ESD protective circuit. The GGNMOS refers to an n-type metal oxide semiconductor (MOS) transistor with its gate grounded. As shown in FIG. 21, a current (ESD current) generated by a surge voltage applied to a pad P flows to ground via the protective circuit ESD to protect main circuits MC.

FIG. 22 shows the relationship between the terminal voltage V of a transistor T and a current I flowing through the transistor T. The transistor T connected as shown in FIG. 21 behaves as shown in FIG. 22. Specifically, the terminal voltage V decreases rapidly on reaching a breakdown voltage (trigger voltage) Vt11 that depends on the characteristics of the transistor T. Subsequently, when the terminal voltage V reaches a predetermined voltage Vt12, the current I increases rapidly. By appropriately setting values for the voltages Vt11 and Vt12, the transistor T performs a desired operation as a protective circuit. Presently, MOS transistors used as the transistor T have a breakdown voltage Vt11 of about 7.7 V. The MOS transistor has a gate insulating film of about 6 nm and a film failure voltage of about 8 V.

Furthermore, an ESD protective circuit is known in which an n-type MOS transistor is used in a forward bias state, compared to the first conventional example in which the transistor is used in a reverse bias state. As shown in FIG. 23 showing a second example, a detecting section D detects a surge voltage, and an output voltage from the detecting section D is amplified by a CMOS inverter. An output signal from the CMOS inverter turns on a MOS transistor Mn2 to cause the surge voltage to flow to ground.

FIG. 24 shows a third conventional example. As shown in FIG. 24, the detecting section D detects a surge voltage to turn on a p-type transistor Mp2. As a result, a potential from a power line Lvd is applied to a base of an npn bipolar transistor Tn3 to turn on the transistor Tn3. Then, the potential at a base of a pnp bipolar transistor Tp1 is drawn to ground to turn on the transistor Tp1. The surge voltage flows to ground via the transistor Tp1 and a resistor R2.

In the first conventional example, if the gate insulating film has a thickness of 6 nm, the breakdown voltage Vt11 is lower than the film failure voltage of the MOS transistor. However, as MOS transistors become more and more fine-grained, the thickness of the gate insulating film decreases. Accordingly, if the gate insulating film of the transistor T has a thickness of, for example, 3 nm, the film failure voltage decreases to about 5 V, and the breakdown voltage Vt11 exceeds the film failure voltage. As a result, before the transistor T operates as a protective circuit, the gate insulating film undergoes electrostatic discharge damage. Thus, an ESD protective is desired which has a breakdown voltage that remains lower than the film failure voltage even if the thickness of the gate insulating film decreases to reduce the film failure voltage.

In the second and third conventional examples, the MOS transistors Mn2 and Mp2 are used under a forward bias condition in contrast with the first conventional example. Consequently, there is no possibility that the gate insulating film undergoes electrostatic discharge damage. However, a decrease in the thickness of the gate insulating film may result in severe damage to the gate insulating film. That is, the durability of the MOS transistors Mn2 and Mp2 decreases.

### BRIEF SUMMARY OF THE INVENTION

According to a first aspect of the present invention, there is provided a semiconductor device having a MOS transistor that allows a surge current to flow between a source and a drain in order to protect main circuits, the MOS transistor comprising: a first conductive type well formed on a surface of a semiconductor substrate and having a first impurity concentration; a gate insulating film disposed on a surface of the well; a gate electrode disposed on the gate insulating film and electrically connected to ground; a source region as the source and a drain region as the drain formed in the surface of the well so as to sandwich a channel region located under the gate electrode, the source region and the drain region having a second conductive type opposite to the first conductive type, one of the source region and the drain region being electrically connected to ground; a first impurity diffusion region of the first conductive type formed along a surface of the source region which faces the channel region, the first impurity diffusion region having a second impurity concentration higher than the first impurity concentration; and a second impurity diffusion region of the first conductive type formed along a surface of the drain region which faces the channel region and separately from the first impurity diffusion region, the second impurity diffusion region having the second impurity concentration.

According to a second aspect of the present invention, there is provided a semiconductor device having a protective circuit which allows a surge current to flow in order to protect main circuits, the device comprising: a surge voltage input section; a detecting section connected to the surge voltage input section and outputting a detection signal on detecting an applied surge voltage; an amplifying section which outputs an amplified signal obtained by amplifying the detection signal; an npn-type first transistor having a base supplied with the amplified signal and a collector electrically connected to the surge voltage input section; and an npn-type second transistor having a base electrically connected to an emitter of the first transistor, a collector electrically connected to the collector of the first transistor, and an emitter electrically connected to ground.

According to a third aspect of the present invention, there is provided a semiconductor device having a protective circuit which allows a surge current to flow in order to protect main circuits, the device comprising: a surge voltage input section; a detecting section connected to the surge voltage input section and outputting a detection signal on detecting an applied surge voltage; an npn-type first transistor having a base supplied with the detection signal and a collector electrically connected to the surge voltage input section; an npn-type second transistor having a base electrically connected to an emitter of the first transistor and an collector electrically connected to the collector of the first transistor; and a thyristor section having an input connected to the surge voltage input section, an output electrically connected to ground, and a trigger signal input connected to an emitter of the second transistor.

### BRIEF DESCRIPTION OF THE SEVERAL VIEWS OF THE DRAWING

FIG. 1 is a sectional view showing a semiconductor device according to a first embodiment of the present invention;

FIG. 2 is a graph showing an impurities profile of a part of FIG. 1;

FIG. 3 is a sectional view schematically showing a part of a manufacturing process for the semiconductor device in FIG. 1;

FIG. 4 is a sectional view showing a step following FIG. 3;

FIG. 5 is a plan view showing a step following FIG. 4;

FIG. 6 is a sectional view showing a step following FIG. 4;

FIG. 7 is a sectional view showing a step following FIG. 6;

FIG. 8 is a graph showing the voltage and current characteristics of a GGNMOS transistor;

FIG. 9 is a graph showing the relationship between the concentration of impurities in an impurity diffusion region and the trigger voltage of the GGNMOS transistor;

FIG. 10 is a graph showing the concentration of impurities in the impurity diffusion region and a leakage voltage;

FIG. 11 is a plan view schematically showing a semiconductor device according to a second embodiment of the present invention;

FIG. 12 is a plan view schematically showing a part of a manufacturing process for the semiconductor device in FIG. 11;

FIG. 13 is a circuit diagram showing a semiconductor device according to a third embodiment of the present invention;

FIG. 14 is a sectional view schematically showing the semiconductor device according to the third embodiment of the present invention;

FIG. 15 is a plan view schematically showing the semiconductor device according to the third embodiment of the present invention;

FIG. 16 is a circuit diagram showing a semiconductor device according to a fourth embodiment of the present invention;

FIG. 17 is a sectional view schematically showing a semiconductor device according to a fifth embodiment of the present invention;

FIG. 18 is a plan view schematically showing the semiconductor device according to the fifth embodiment of the present invention;

FIG. 19 is a sectional view schematically showing a semiconductor device according to a sixth embodiment of the present-invention;

FIG. 20 is a plan view schematically showing the semiconductor device according to the sixth embodiment of the present invention;

FIG. 21 is a diagram showing a first conventional example of a protective circuit;

FIG. 22 is a graph showing the current and voltage characteristics of the protective circuit in FIG. 21;

FIG. 23 is a diagram showing a second conventional example of a protective circuit; and

FIG. 24 is a diagram showing a third conventional example of a protective circuit.

### DETAILED DESCRIPTION OF THE INVENTION

Embodiments of the present invention will be described below with reference to the drawings. In the description below, components having substantially the same functions and configurations are denoted by the same reference numerals. Duplicate description will be given only when required.

(First Embodiment)

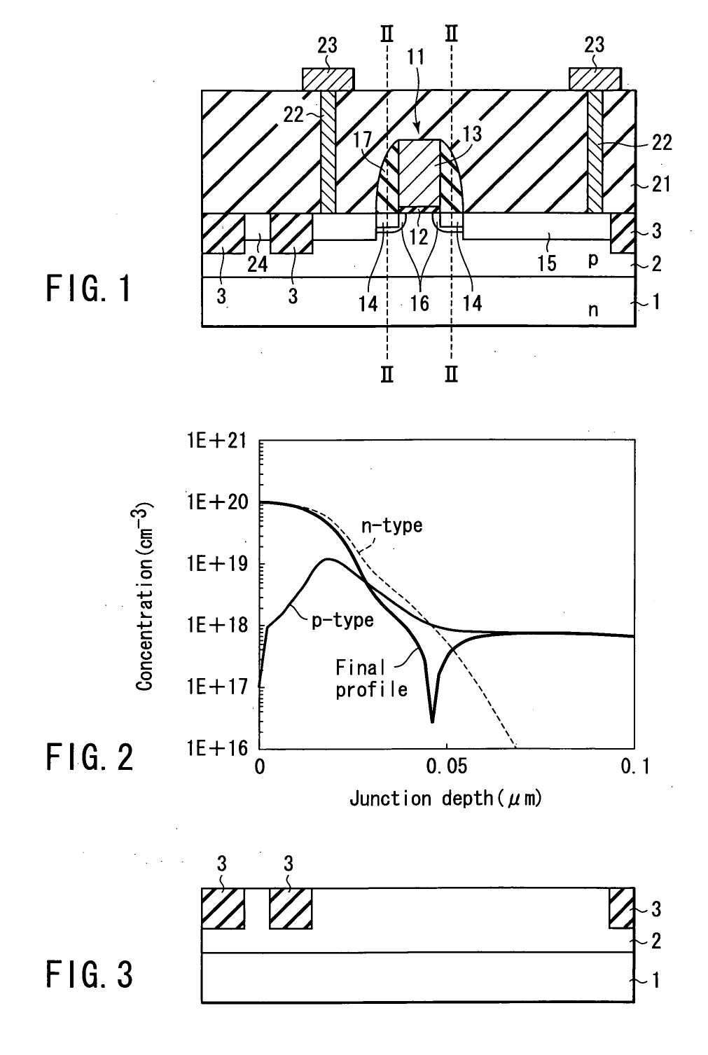

FIG. 1 is a sectional view showing a semiconductor device according to a first embodiment of the present invention. As shown in FIG. 1, a p-type well 2 is formed on a surface of an n-type semiconductor substrate 1 composed of, for example, silicon. An isolation film 3 is formed on a surface of the p well 2 to a depth of, for example, 200 to 350 nm.

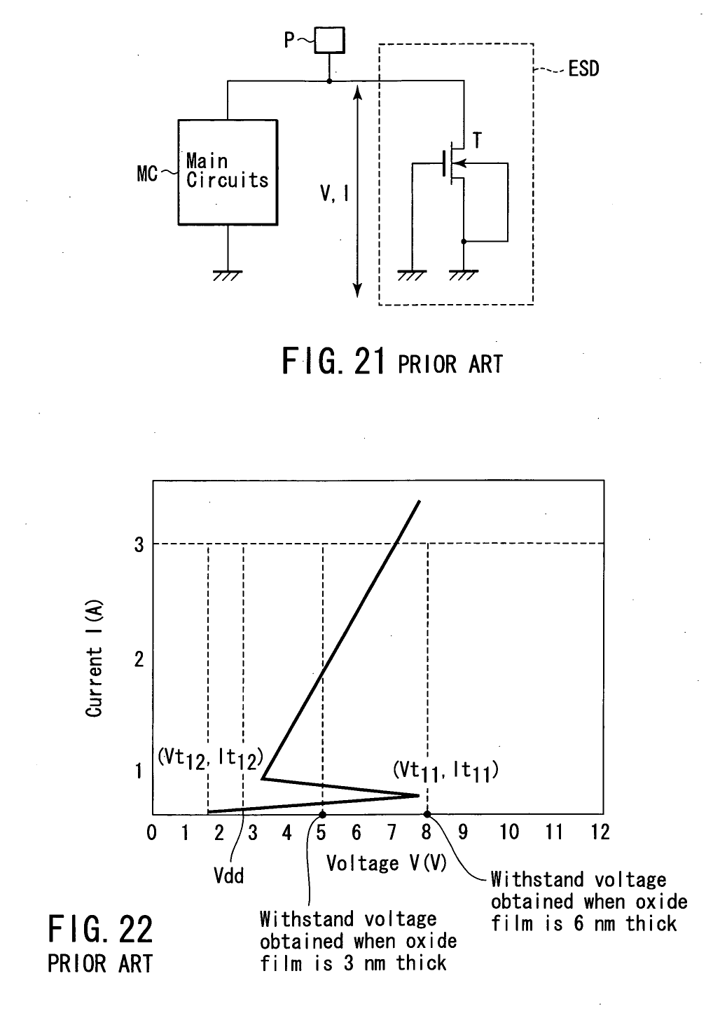

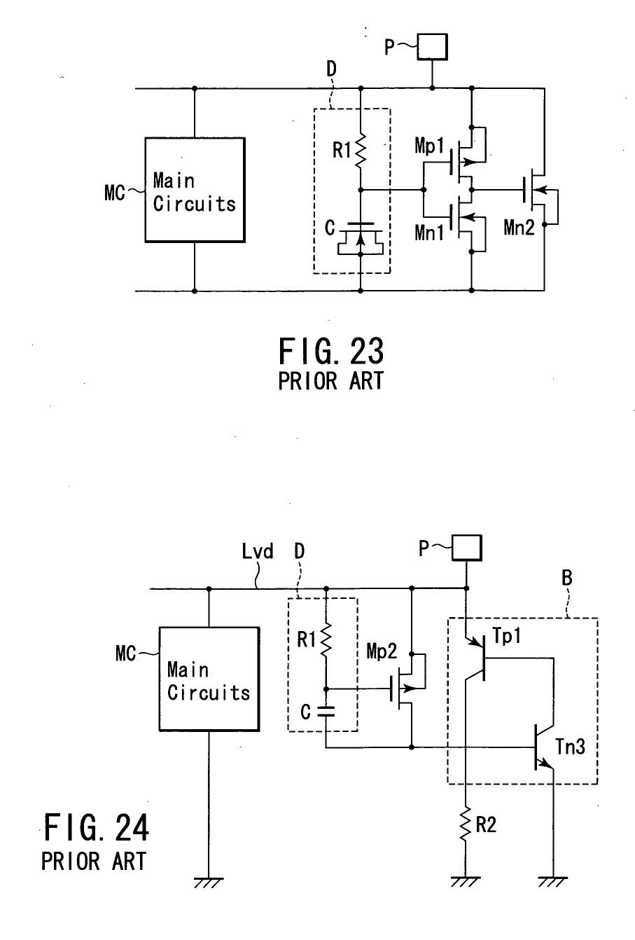

An n-type MIS transistor 11 is provided on the p well 2. The transistor 11 is used as a GGNMOS functioning as the ESD protective circuit shown in FIG. 21. The transistor 11 has a gate insulating film 12, a gate electrode 13, a low-concentration source/drain diffusion region 14, high-concentration source/drain diffusion region 15, an impurity diffusion region 16, and a side wall insulating film 17.

The gate electrode 13 is provided on the well 2 (on the semiconductor substrate 1) and between the source and drain of the low-concentration source/drain diffusion region 14 via the gate insulating film 12. The gate insulating film 12 is composed of a silicon oxide film having a thickness of, for example, 1 to 6 nm. The gate electrode 13 is composed of polycrystalline silicon having a thickness of, for example, 50 to 200 nm.

The side wall insulating film 17 covers the sides of the gate insulating film 12 and gate electrode 13. The side wall insulating film 17 is composed of, for example, a silicon oxide film or a silicon nitride film. Moreover, it may be composed a silicon oxide film or a silicon nitride film one of which is used as a liner film with the other provided outside the liner film.

The p-type high-concentration source/drain diffusion region (source/drain contact region) 15 is formed in the surface of the p well 2 so as to extend, for example, from the isolation film 3 to the vicinity of the side wall insulating film 17. The p-type low-concentration source/drain diffusion region (source/drain extension region) 14 is formed in the surface of the p well 2 so as to extend from an end of the high-concentration source/drain diffusion region 15 to an end of the gate electrode 13. The low-concentration source/drain diffusion region 14 is formed to be shallower than the high-concentration source drain region 15.

The p-type impurity diffusion region 16 is formed along the respective boundaries of the low-concentration source/drain diffusion region 14 and at least along that surface of the low-concentration source/drain diffusion region 14 which faces a channel region. The impurity diffusion region 16 has a higher impurity concentration than the p well 2. An end of the impurity diffusion region 16 extends over a surface of the semiconductor substrate 1 to reach the end of the gate electrode 13 as in the case with the low-concentration source/drain diffusion region 14. The impurity diffusion region 16 is formed to be slightly deeper than the low-concentration source/drain diffusion region 14.

An interlayer insulating film 21 is provided all over the surface of the semiconductor substrate 1. The interlayer insulating film 21 is composed of for example, tetraethylorthosilicate (TEOS), boron phosphorous silicate glass (BPSG), silicon nitride (SiN), or the like. Contact plugs 22 are provided in the interlayer insulating film 21 so as to reach the high-concentration source/drain region 15. The contact plugs 22 are composed of a barrier metal consisting of, for example, titanium (Ti) or titanium nitride (TiN), or tungsten (W) or the like. Interconnect layers 23 are provided on the respective contact plugs 22 in the interlayer insulating film 21. A p-type contact region 24 formed on the surface of the p well 2 applies a potential to the channel region of the transistor 11.

FIG. 2 is a graph showing an impurity profile of the semiconductor device taken along line II-II in FIG. 1. As shown in FIG. 2, the p-type impurity diffusion region 16 is formed to be deeper than the n-type low-concentration source/drain diffusion region 14.

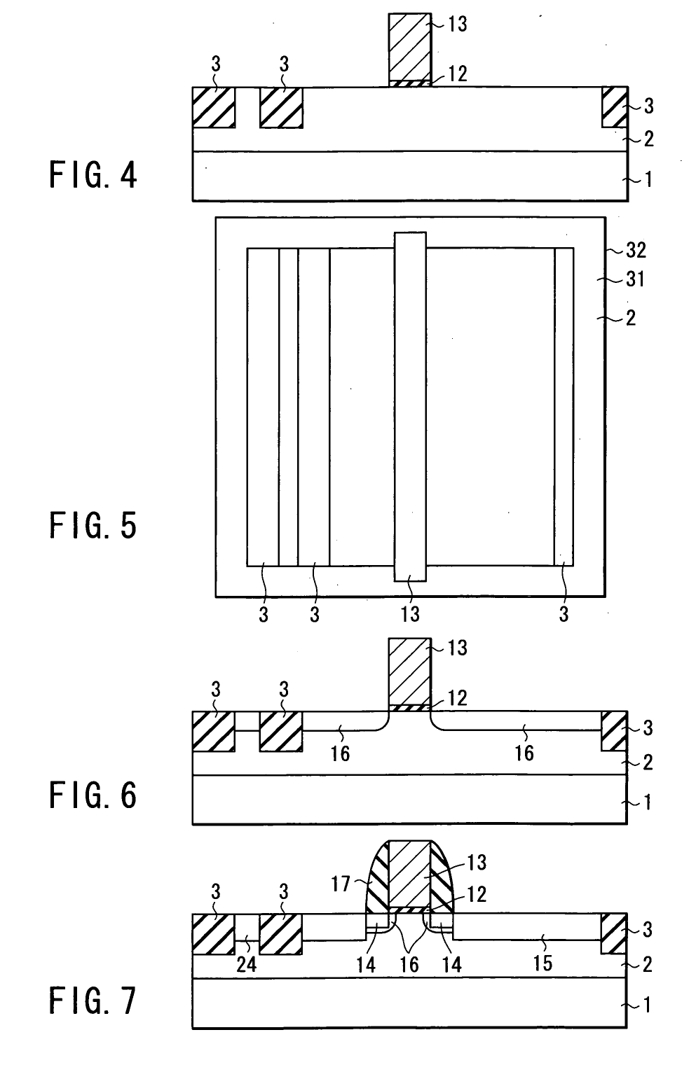

Now, with reference to FIGS. 3 to 6, description will be given of a manufacturing method for the semiconductor device in FIG. 1. FIGS. 3, 4, 6, and 7 are sectional views sequentially showing the manufacturing process for the semiconductor device in FIG. 1. FIG. 5 is a plan view showing a step following FIG. 4. As shown in FIG. 3, the isolation film 3 is formed on the surface of the semiconductor substrate 1 using a Lithography-process and an etching technique. Then, the p well 2 is formed on the surface of the semiconductor substrate 1 by ion implantation. Boron is implanted under typical ion implantation conditions, i.e. at 260 keV and 2.0×10¹³ cm⁻². Then, the lithography process and the etching technique are used to implant ions in a region of the transistor in which a channel is to be formed, in order to adjust thresholds. Then, arsenic is implanted under typical ion implantation conditions, i.e. 100 keV and 1.5×10¹³ cm⁻². Then, heat treatment is carried out to activate the implanted ions.

Then, as shown in FIG. 4, the gate insulating film 12 is formed using a thermal oxidation method and an low pressure chemical vapor deposition (LPCVD) method. A material film for the gate electrode 13 is then deposited all over the surface of the semiconductor substrate 1. Then, the gate electrode 13 is formed using the lithography process and an etching technique such as reactive ion etching (RIE). The thermal oxidation method is then used to form a post-oxide film (not shown) made of SiO₂ or the like, on the surface of the gate electrode 13.

Then, as shown in FIGS. 5 and 6, a mask material 32 having an opening slightly larger than the p well 2 is formed on the semiconductor substrate 1 using the lithography process and the etching technique. The impurity diffusion region 16 is then formed by ion implantation using the mask material 32 and the gate electrode 13 as a mask. As an example of ion implantation conditions, boron fluoride (BF₂) is implanted at 30 to 60 keV and 1×10¹³ cm⁻² to 10×10¹³ cm⁻². Then, the mask material is removed.

Then, as shown in FIG. 7, the low-concentration source/drain diffusion region 14 is formed using the lithography process, the etching technique, the ion implantation method, and the thermal oxidation method. As the ion implantation in this case, for example, As is used at 1 to 5 keV, 5×10¹⁴ cm⁻² to 1.5×10¹⁵ cm⁻². Then, the side wall insulating film 17 is formed using the LPCVD method and the etching technique such as RIE. The lithography process, the etching technique, and the ion implantation method are then used to form the high-concentration source/drain region 15 and contact region 24 in which, for example, phosphorous (P), arsenic (As), and the like are implanted. Then, titanium (Ti), cobalt (Co), nickel (Ni), or the like is used to form silicide on the high-concentration source/drain diffusion region 15 through a sputtering process and heat treatment. To prevent the silicide from being partly removed when contact holes are formed, a film may be provided on the silicide which has a higher selection rate than the silicide during RIE.

Then, as shown in FIG. 1, the interlayer insulating film 21 is formed on the semiconductor substrate 1. Contact holes are then formed in the interlayer insulating film 21. Then, the contact holes are filled with a barrier metal, and a material film for the contact plugs 22. The interconnect layer 23 is then formed.

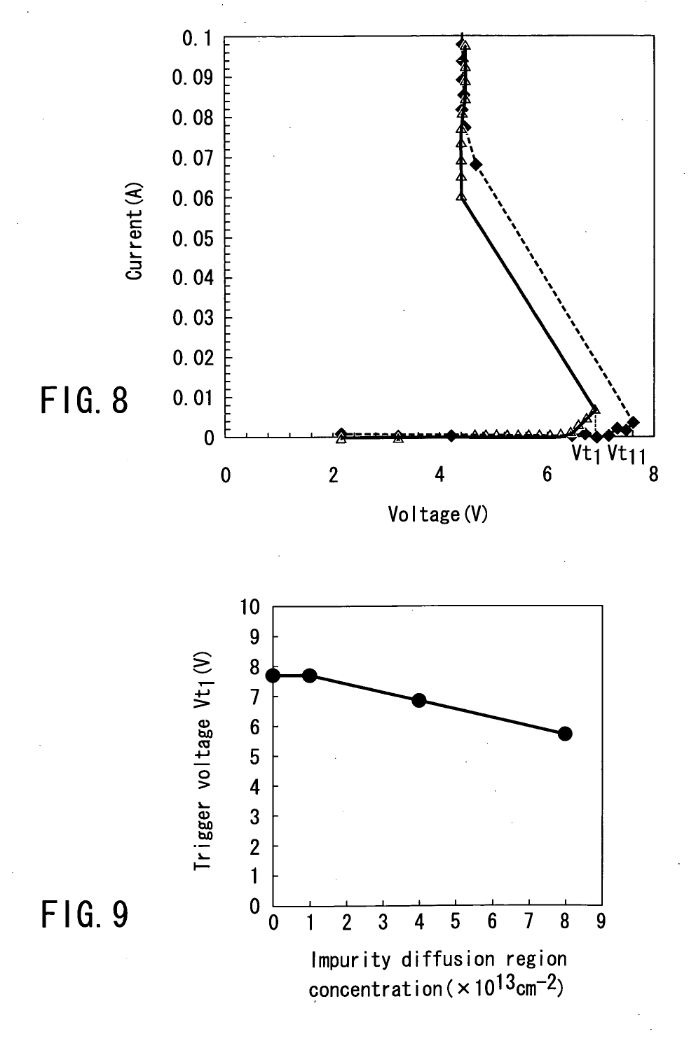

Now, description will be given of the effects of the semiconductor device configured as described above. FIG. 8 is a graph showing the voltage and current characteristics of a GGNMOS transistor. In FIG. 8, the broken line indicates a case without the impurity diffusion region 16, i.e. the first conventional example. On the other hand, the solid line in FIG. 8 indicates a case with the impurity diffusion region 16 formed by the ion implantation under the above conditions. As shown in FIG. 8, in the first conventional example, a trigger voltage Vt1 is about 7.7 V. In contrast, according to the first embodiment of the present invention, the trigger voltage Vt11 is about 6.5 V.

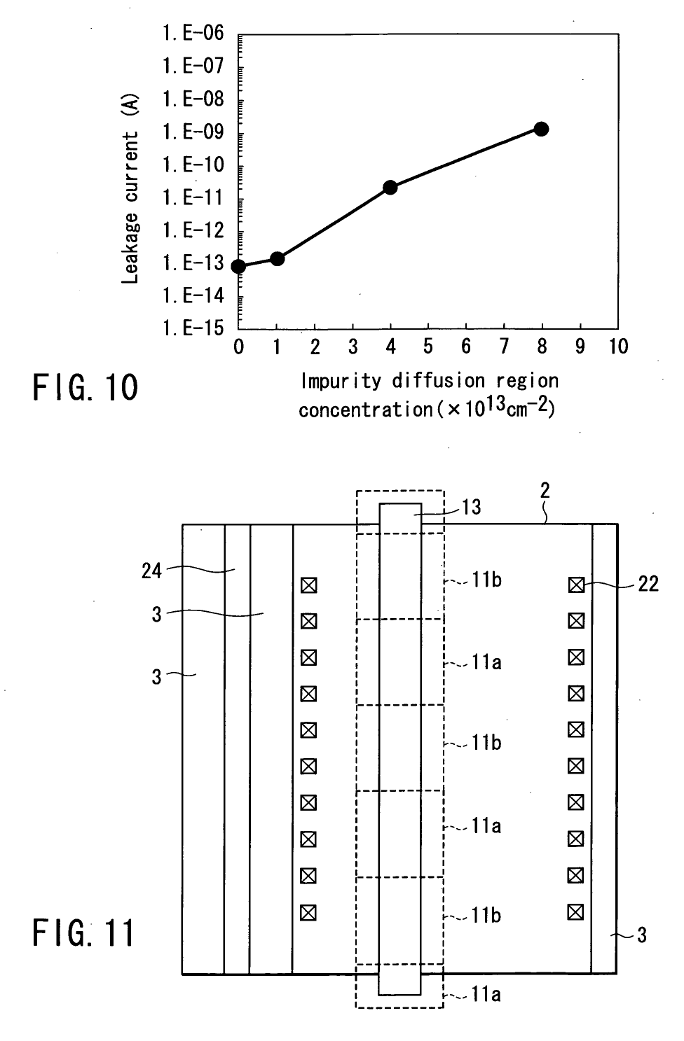

FIG. 9 shows the relationship between the concentration of impurities in the impurity diffusion region 16 and the trigger voltage of the transistor 11. FIG. 10 shows the concentration of impurities in the impurity diffusion region 16 and a leakage voltage that may occur between the source and drain of the source/drain diffusion region-14. As shown in FIG. 9, when the impurity diffusion region 16 is formed, if, for example, implantation energy is fixed, the trigger voltage Vt1 can be reduced by increasing the concentration of impurities in the impurity diffusion region. That is, the effects of the first embodiment described later are more marked. However, as shown in FIG. 10, also with the same implantation energy, the leakage current increases by increasing the concentration of impurities in the impurity diffusion region. Accordingly, it is important to determine the concentration of impurities in the impurity diffusion region 16 considering the value of an allowable leakage current and the value of a desired trigger voltage.

In the semiconductor device according to the first embodiment, the p-type impurity diffusion region 16 in the GGNMOS transistor 11 is formed along the n-type low-concentration source/drain diffusion region 14 so as to sandwich the channel region between the pieces of the p-type impurity diffusion region 16. This makes it possible to reduce the trigger voltage Vt1 of the GGNMOS transistor 11. Consequently, even if the film failure voltage of the transistor 11 decreases consistently with the thickness of the gate insulating film 12 in the transistor 11, it is possible to prevent the transistor 11 from undergoing electrostatic discharge damage before the trigger voltage Vt1 is reached.

Furthermore, the trigger voltage Vt1 can be arbitrarily set by adjusting the concentration of impurities in the impurity diffusion region 16. Thus, the trigger voltage Vt1 can be set with an appropriate margin with respect to the film failure voltage of the transistor 11.

(Second Embodiment)

In the first embodiment, ions are implanted all over the surface of the transistor 11 to form the impurity diffusion region 16. In contrast, in the second embodiment, ions are implanted only partly in the extending gate electrode 13.

FIG. 11 is a plan view schematically showing a semiconductor device according to a second embodiment of the present invention. As shown in FIG. 11, the transistor 11 has first regions 11a and second regions 11b along the direction in which the gate electrode 13 extends. An impurity diffusion region 16 similar to that in the first embodiment is formed in each of the first regions 11a. On the other hand, the impurity diffusion region 16 is not formed in the second regions 11b. The cross section of the first region 11a is similar to that shown in FIG. 1. The cross section of the second region 11a is the same as that shown in FIG. 1 but from which the impurity diffusion region 16 is omitted. An arbitrary number of first regions 11a are arranged at arbitrary positions along the gate electrode 13.

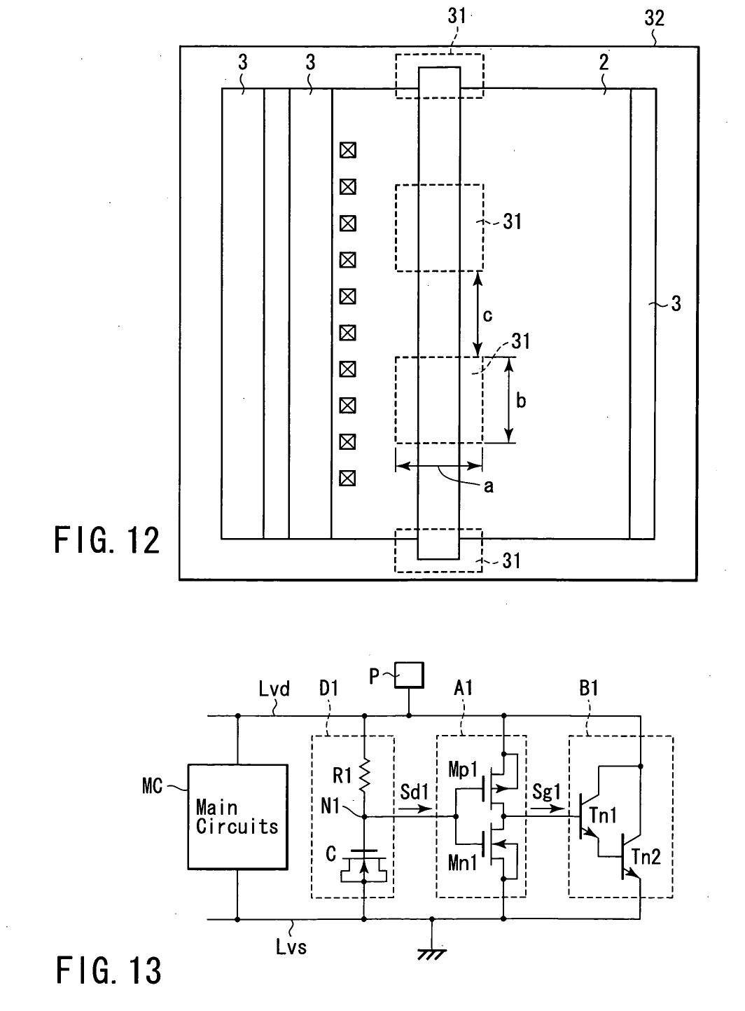

Now, with reference to FIG. 12, description will be given of a manufacturing method for a semiconductor device configured as shown in FIG. 11. The steps shown in FIGS. 1 to 3 for the first embodiment are also executed in the second embodiment. After the step in FIG. 3, the mask material 32 having openings 31 along the gate electrode 13 is formed on the semiconductor substrate 1. The openings 31 correspond to the regions in which the first regions 11a are to be formed. In an example of a specific configuration, a dimension La in a direction crossing the gate electrode 13 and a dimension Lb in the extending direction of the gate electrode 13 are each between 400 and 1,000 nm. The spacing Lc between the openings 31 is also between 400 and 1,000 nm. The impurity diffusion region 16 is formed by implanting ions using the mask material 32 as a mask and using the same conditions as those used in the steps in FIGS. 5 and 6 of the first embodiment. The subsequent steps are the same as those in the first embodiment.

Now, description will be given of the effects of the semiconductor device configured as described above. As described above, when the impurity diffusion region 16 is formed, the leakage current from the transistor 11 increases, though this increase depends on the value of the concentration of impurities. Therefore, in the second embodiment, the first regions 11a constitute a part of the transistor 11, and the impurity diffusion region 16 formed only in the first regions 11a. Then, a leakage current does not occur in the overall transistor but may occur only in the first regions 11a. This reduces the total amount of leakage current that may occur in the transistor 11.

On the other hand, the effects described in the first embodiment are obtained by simply arranging at least one first region 11a at any position along the gate electrode 13. However, sufficient effects may not be obtained if the first regions 11a take up too small a percentage of the total width of the gate electrode 13, having a large gate width. Thus, the spacing Lc between the first regions 11a is set to take up 77.5 to 92.5%, preferably 85 to 92%, and more preferably 90 to 92.5% of the gate width of the gate electrode 13.

In the semiconductor device according to the second embodiment, the impurity diffusion region 16 is not formed entirely along the gate electrode 13 but partly along it. Therefore, it is possible to produce effects similar to those of the first embodiment, while reducing the possible leakage current compared to the first embodiment.

(Third Embodiment)

In the first and second embodiments, the ESD protective element is a GGNMOS transistor. A third embodiment employs a bipolar transistor.

FIG. 13 is a circuit diagram showing a semiconductor device according to a third embodiment of the present invention. As shown in FIG. 13, an input pad P for a surge voltage (surge voltage input section) is connected to a power line Lvd. Main circuits MC, a detecting section D1, an amplifying section A1, and a surge current bypass section B1 are connected between the power line Lvd and a ground potential line Lvs.

The detecting section D1 outputs a detection signal Sd1 on detecting an input of a surge voltage. The detecting section D1 is composed of, for example, a resistor R1 and a capacitor C connected in series. The power line Lvd connects to an end of the resistor R1 which is opposite a connection node N1 connected to the capacitor C. Ground potential line Lvs connects to an end of the capacitor C which is opposite the connection node N1.

The amplifying section A1 amplifies the detection signal Sd1 and outputs a trigger signal Sg1. The amplifying section A1 is composed of a CMOS inverter circuit consisting of a PMOS transistor Mp1 and an NMOS transistor Mn1.

The surge current bypass section B1 is turned on when supplied with the trigger signal Sg1. The surge current bypass section B1 short-circuits the power line Lvd and ground potential line Lvs to prevent a surge current from flowing into the main circuits MC. The surge current bypass section B1 is composed of Darlington pair npn transistors Tn1 and Tn2. Specifically, the transistor Tn1 has a base supplied with the trigger signal Sg1 and a collector connected to the power line Lvd. The transistor Tn2 has a collector connected to the power line Lvd, a base is connected to an emitter of the transistor Tn1, and an emitter connected to ground potential line Lvs.

The transistors Tn1 and Tn2 have a current amplification ratio β of about 5 to 10. Accordingly, the current amplification ratio of the surge current bypass section B1 is β×β=25 to 100. The transistors Tn1 and Tn2 may be elements constructed using a normal MOS transistor forming process as described later.

Now, description will be given of operations of the circuit configured as shown in FIG. 13. When a surge voltage is applied, the amplifying section A1 applies a bias between the base and emitter of the transistor Tn1 to turn on the transistor Tn1. The current flowing through the transistor Tn2 has the value of the current flowing between the base and emitter of the transistor Tn1, multiplied by the current amplification ratio of the surge current bypass section B1.

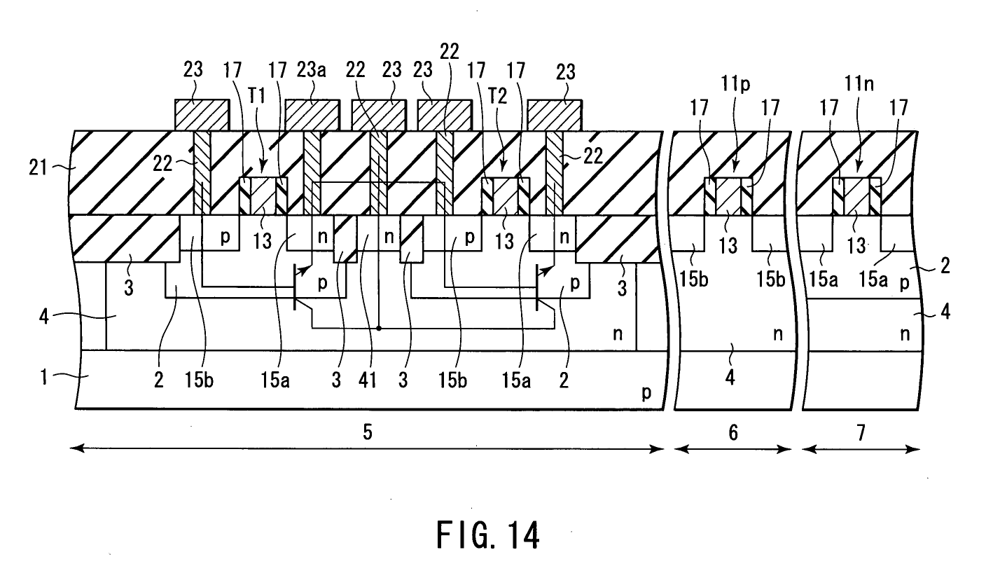

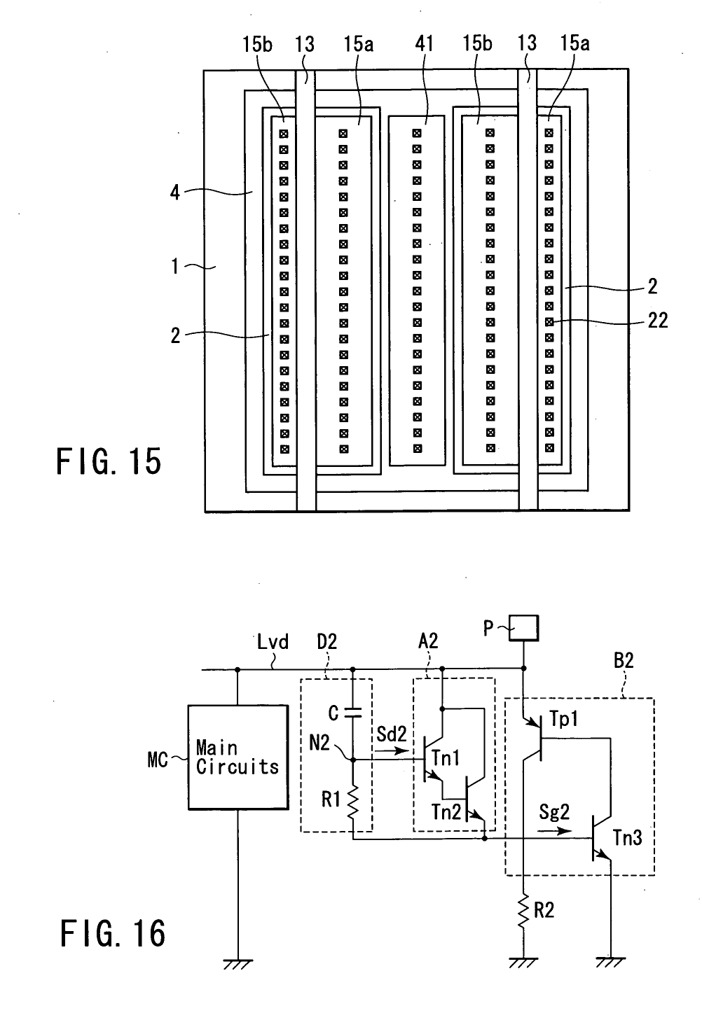

Now, description will be given of a method of implementing the bipolar transistors Tn1 and Tn2 shown in FIG. 13, using a MOS transistor forming process. FIG. 14 is a sectional view schematically showing the semiconductor device according to the third embodiment of the present invention. It also schematically shows the bipolar transistors Tn1 and Tn2 of FIG. 13. FIG. 15 is a plan view of a bipolar-transistor-formed region 5, shown in FIG. 14.

As shown in FIGS. 14 and 15, the bipolar-transistor-formed region 5, a PMOS transistor formed region 6, and an NMOS-transistor-formed-region 7 are formed. An n well 4 is formed by for example, implanting arsenic in the surface of the p-type semiconductor substrate 1 at 1,200 keV and 1×10¹³ cm⁻². In the n well 4, p wells 2 are formed separately from each other. Isolation films 3 are each formed between the n well 4 and the corresponding p well 2.

A PMOS transistor 11p is formed in the PMOS transistor-formed-region 6. The PMOS transistor 11p has a pair of high-concentration source/drain diffusion regions 15b and the gate electrode 13 provided on a surface of the n well 4 via a gate insulating film (not shown). The high-concentration source/drain diffusion regions 15b are formed on the surface of the in well 4 and have a higher impurity concentration than the p wells 2. The PMOS transistor 11p may have the p-type low-concentration source/drain diffusion region 14.

An NMOS transistor 11n is formed in the NMOS-transistor-formed-region 7. The NMOS transistor 11n has a pair of high-concentration source/drain diffusion regions 15a and the gate electrode 13 provided on a surface of the p well 2 via the gate insulating film (not shown). The high-concentration source/drain diffusion regions 15a are formed on the surface of the p well 2. The NMOS transistor 11n may have the n-type low-concentration source/drain diffusion region 14.

Transistor structures T1 and T2 are provided on the respective p wells 2 in the bipolar-transistor formed-region 5. The transistor structures T1 and T2 each have the high-concentration source/drain diffusion regions 15a and 15b and the gate electrode 13. The high-concentration source/drain diffusion regions 15a constituting the transistor structures T1 and T2, NMOS transistor 11n, and PMOS transistor 11p is formed using the same process. The high-concentration source/drain diffusion regions 15a thus have substantially the same impurity concentration. This also applies to the high-concentration source/drain diffusion layers 15b.

Furthermore, the gate electrodes 13 constituting the transistor structures T1 and T2, NMOS transistor 11n, and PMOS transistor 11p are formed using the same process. Accordingly, the gate electrodes 13 are composed of substantially the same material. A contact region 41 having a higher impurity concentration than the n well 4 is formed on the surface of the n well 4.

The transistor structures T1 and T2 constitute the transistors Tn1 and Tn2 each having the high-concentration source/drain diffusion region as a base, the n well 4 as a collector, and the high-concentration source/drain diffusion region 15a as an emitter. An interconnect layer 23a is connected to the high-concentration source/drain diffusion region 15a of the transistor structure T1. An interconnect layer 23b is connected to the high-concentration source/drain diffusion region 15b of the transistor structure T2. Moreover, the interconnect layers 23a and 23b are electrically connected. The n well 4, constituting the collectors of the transistors Tn1 and Tn2, is provided with a potential via the contact region 41.

In the semiconductor device according to the third embodiment, the surge current bypass section B1 of the ESD protective circuit is composed of the bipolar transistors Tn1 and Tn2. Compared to MOS transistors, bipolar transistors do not have any fragile portions such as the gate insulating film, to which a voltage is applied for each operation. Consequently, bipolar transistors are superior to MOS transistors in terms of durability. By constructing the surge current bypass section B1 using the bipolar transistors Tn1 and Tn2, it is possible to provide a semiconductor device having a highly durable ESD protective circuit.

Furthermore, according to the third embodiment, the transistors Tn1 and Tn2 can be formed using the same forming process as that for the MOS transistors 11n and 11p. In this case, the transistors Tn1 and Tn2 can be implemented by changing the pattern of the gate electrode 13 and the mask used to inject impurities. Consequently, the bipolar transistors Tn1 and Tn2 can be formed without drastically changing the manufacturing process.

Furthermore, according to the third embodiment, the Darlington pair transistors Tn1 and Tn2 constitute the surge current bypass section B1. In general, bipolar transistors formed utilizing a MOS transistor forming process have a low-current amplification ratio owing to the conditions for injected impurities and the concentration of the impurities. Thus, the Darlington pair transistors Tn1 and Tn2 serve to compensate for the low current amplification ratio. Therefore, a surge current can be efficiently directed to ground line Lvs.

(Fourth Embodiment)

In a fourth embodiment, the surge current bypass section and the amplifying section are composed of bipolar transistors.

FIG. 16 is a circuit diagram showing a semiconductor device according to the fourth embodiment of the present invention. As shown in FIG. 16, a detecting section D2, an amplifying section A2, and a surge current bypass section B2 are connected between the power line Lvd and an interconnect L1.

The detecting section D2 is composed of, for example, the resistor R1 and capacitor C connected in series. The power line Lvd connects to the end of the capacitor C which is opposite a connection node N2 connected to the resistor R1. The interconnect L1 connects to the end of the resistor R1 which is opposite the connection node N2.

The amplifying section A2 amplifies a detection signal Sd2 and outputs a trigger signal Sg2. The amplifying section A2 is composed of the Darlington pair transistors Tn1 and Tn2.

The surge current bypass section B2 is composed of a pnp transistor Tp1 and an npn transistor Tn3 which are connected together as a thyristor. Specifically, the transistor Tp1 has its emitter connected to the power line Lvd and its collector connected to ground via a resistor R2 that generates a bias. The transistor Tn3 has its collector connected to the base of the transistor Tp1, its emitter connected to ground, and its base supplied with the trigger signal Sg2. The input of the thyristor corresponds to the emitter of the transistor Tp1, while its output corresponds to the emitter of the transistor Tn3.

Now, description will be given of operations of the circuit configured as shown in FIG. 16. When a surge voltage is input, the detecting section D2 outputs a detecting signal Sd2. When the detection signal Sd2 is supplied to the amplifying section A2, a bias is applied between the base and emitter of the transistor Tn1 to turn on the transistor Tn1. When the transistor Tn1 is turned on, a bias is applied to the base of the transistor Tn2 as a result the transistor Tn2 is turned on.

Following turn-on of the transistor Tn2, the trigger signal Sg2 is supplied to the surge current bypass section B2, which leads the transistor Tn3 to turn on. When the transistor Tn3 is turned on, the transistor Tp1, i.e. the thyristor structure, is turned on. As a result, a surge current flows to ground via the surge current bypass section B2.

The sectional structure of the transistors Tn1 and Tn2 of the amplifying section A2 in FIG. 16 is similar to that in the third embodiment. Its description is thus omitted.

In the semiconductor device according to the fourth embodiment, the amplifying section A2 of the ESD protective circuit is composed of the Darlington pair bipolar transistors Tn1 and Tn2 as in the case with the third embodiment. Thus, the amplifying section A2 can efficiently amplify the detection signal Sd2 for the same reason as that in the third embodiment. Therefore, the efficiently amplified trigger signal Sg2 makes it possible that the surge current bypass section B2 allows a large surge current to bypass the main circuits MC.

Furthermore, the fourth embodiment does not use any MOS transistors, thus providing a semiconductor device including a highly durable ESD protective circuit. Moreover, effects similar to those of the third embodiment can be produced because the amplifying section A2 is composed of bipolar transistors formed utilizing the process of forming MOS transistors.

(Fifth Embodiment)

A fifth embodiment relates to the structure of a semiconductor device that can implement the circuits configured according to the third and fourth embodiments. Specifically, in the third and fourth embodiments, a structure similar to the gate electrode 13 is used to electrically separate the high-concentration source/drain diffusion regions 15a and 15b from each other. In contrast, the fifth embodiment uses the isolation film 3.

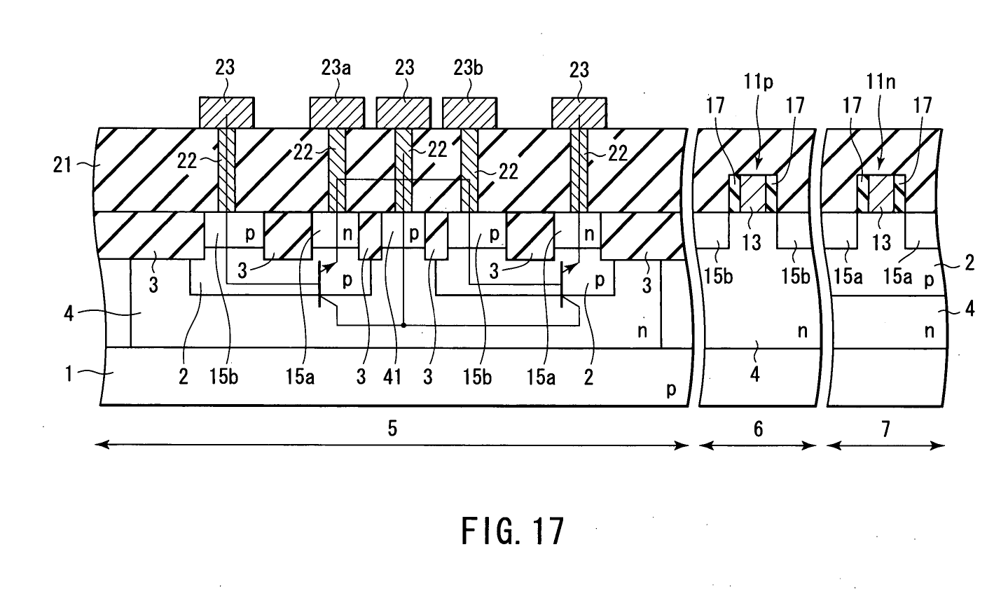

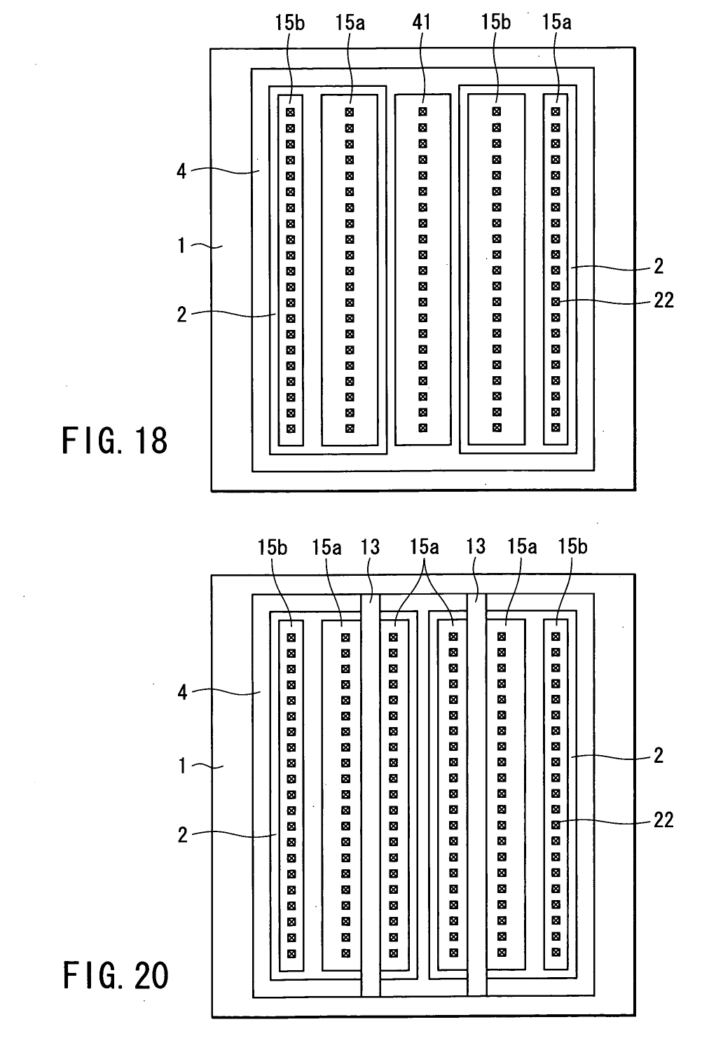

FIG. 17 is a sectional view schematically showing a semiconductor device according to the fifth embodiment of the present invention. It is a sectional view schematically showing the bipolar transistors Tn1 and Tn2, shown in FIGS. 13 and 16. FIG. 18 is a plan view of the bipolar-transistor-formed-region 5.

As shown in FIGS. 17 and 18, the isolation film 13 is provided between the high-concentration source/drain diffusion regions 15a and 15b. The gate electrode 13 is not provided on the semiconductor substrate 1 in this portion. The other arrangements are similar to those of the third embodiment.

The semiconductor device according to the fifth embodiment produces effects similar to those of the third and fourth embodiments.

(Sixth Embodiment)

In the fourth and fifth embodiments, each of the transistors Tn1 and Tn2 is implemented using what is called a vertical bipolar transistor. In contrast, a sixth embodiment uses what is called horizontal bipolar transistors.

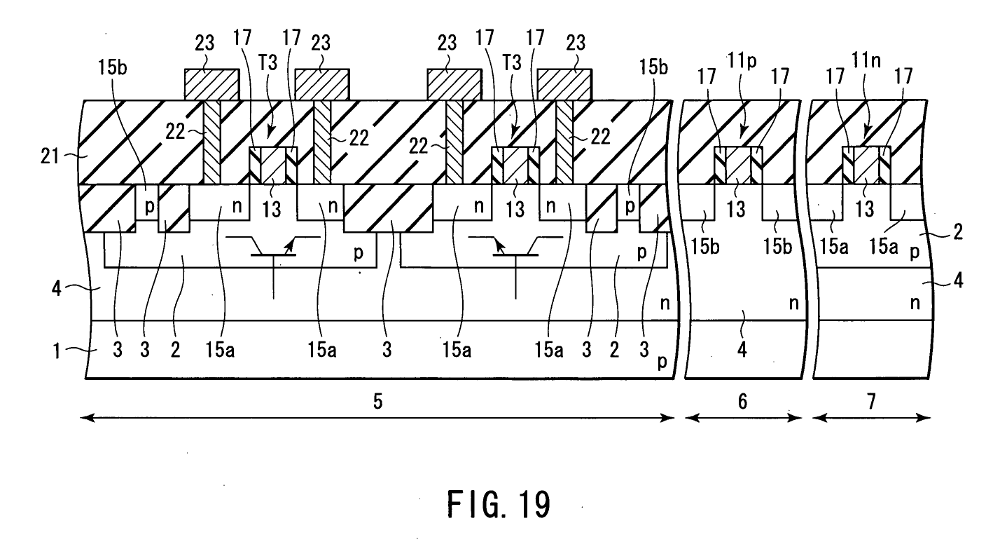

FIG. 19 is a sectional view schematically showing a semiconductor device according to the sixth embodiment of the present invention. It shows the semiconductor device that can use the MOS transistor forming process to implement the circuit configured as shown in FIG. 13 and FIG. 16. FIG. 20 is a plan view of the bipolar-transistor-formed-region 5, shown in FIG. 19.

As shown in FIGS. 19 and 20, transistor structures T3 are provided in the p well 2. The transistor structure T3 has the n-type high-concentration source/drain diffusion regions 15a and the gate electrode 13. A potential is applied to the p well 4 via the source/drain diffusion regions 15b (contact regions), arranged on the surface of the p well 4.

The transistor structures T3 constitute the transistors Tn1 and Tn2 each having the p well 4 as a base, and the high-concentration source-drain diffusion regions 15a as a collector and an emitter. The emitter of one of the two transistor structures T3 is electrically connected to the base of the other by an interconnect layer and contacts. This implements a Darlington pair. The other arrangements are similar to those of the third embodiment.

The semiconductor device according to the sixth embodiment can produce effects similar to those of the third and fourth embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device having a MOS transistor that allows a surge current to flow between a source and a drain in order to protect main circuits, the MOS transistor comprising:
a first conductive type well formed on a surface of a semiconductor substrate and having a first impurity concentration;
a gate insulating film disposed on a surface of the well;
a gate electrode disposed on the gate insulating film and electrically connected to ground;
a source region as the source and a drain region as the drain formed in the surface of the well so as to sandwich a channel region located under the gate electrode, the source region and the drain region having a second conductive type opposite to the first conductive type, one of the source region and the drain region being electrically connected to ground;
a first impurity diffusion region of the first conductive type formed along a surface of the source region which faces the channel region, the first impurity diffusion region having a second impurity concentration higher than the first impurity concentration; and
a second impurity diffusion region of the first conductive type formed along a surface of the drain region which faces the channel region and separately from the first impurity diffusion region, the second impurity diffusion region having the second impurity concentration.

2. The device according to claim 1, wherein each of the first impurity diffusion region and the second impurity diffusion region extends in a direction in which the gate electrode extends.

3. The device according to claim 1, further comprising:
a third impurity diffusion region of the first conductive type formed at a position away from the first impurity diffusion region in the extending direction of the gate electrode, the third impurity diffusion region extending along the surface of the source region which faces the channel region, the third impurity diffusion region having the second impurity concentration; and
a fourth impurity diffusion region of the first conductive type formed at a position away from the second impurity diffusion region in the extending direction of the gate electrode, the fourth impurity diffusion region extending along the surface of the drain region which faces the channel region, the fourth impurity diffusion region having the second impurity concentration.

4. A semiconductor device having a protective circuit which allows a surge current to flow in order to protect main circuits, the device comprising:
a surge voltage input section;
a detecting section connected to the surge voltage input section and outputting a detection signal on detecting an applied surge voltage;
an amplifying section which outputs an amplified signal obtained by amplifying the detection signal;
an npn-type first transistor having a base supplied with the amplified signal and a collector electrically connected to the surge voltage input section; and
an npn-type second transistor having a base electrically connected to an emitter of the first transistor, a collector electrically connected to the collector of the first transistor, and an emitter electrically connected- to ground.

5. The device according to claim 4, wherein each of the first transistor and the second transistor comprises:
an n-type first well formed in a surface of a substrate and functioning as the collector;
a p-type second well formed in a surface of the first well and functioning as the base; and
an n-type first impurity diffusion region formed in a surface of the second well and functioning as the emitter.

6. The device according to claim 5, further comprising:
a p-type second impurity diffusion region formed in the surface of the second well away from the first impurity diffusion region and having a higher impurity concentration than the second well.

7. The device according to claim 6, further comprising:
a gate electrode structure formed in the surface of the second well between the first impurity diffusion region and the second impurity diffusion region.

8. The device according to claim 7, further comprising:
a first MOS transistor comprising two n-type third impurity diffusion regions each formed in the surface of the semiconductor substrate and having the same impurity-concentration as the first impurity-diffusion region and a first gate electrode disposed on the surface of the semiconductor substrate between the two third impurity diffusion regions via the gate insulating film; and
a second MOS transistor comprising two p-type fourth impurity diffusion regions each formed in the surface of the semiconductor substrate and having the same impurity concentration as the second impurity diffusion region and a second gate electrode disposed on the surface of the semiconductor substrate between the two fourth impurity diffusion regions via the gate insulating film.

9. The device according to claim 8, wherein the gate electrode structure, the first gate electrode, and the second gate electrode are derived from the same material.

10. The device according to claim 6, further comprising an isolation film formed in the surface of the second well between the first impurity diffusion region and the second impurity diffusion region.

11. The device according to claim 10, further comprising:
a first MOS transistor comprising two n-type third impurity diffusion regions each formed in the surface of the semiconductor substrate and having the same impurity concentration as the first impurity diffusion region and a gate electrode disposed on the surface of the semiconductor substrate between the two third impurity diffusion regions via the gate insulating film; and
a second MOS transistor comprising two p-type fourth impurity diffusion regions each formed in the surface of the semiconductor substrate and having the same impurity concentration as the second impurity diffusion region and a gate electrode disposed on the surface of the semiconductor substrate between the two fourth impurity diffusion regions via the gate insulating film.

12. The device according to claim 4, wherein each of the first transistor and the second transistor comprises:
a p-type first well formed in the surface of the substrate and functioning as the base;
an n-type first impurity diffusion region formed in a surface of the first well and functioning as the collector; and
an n-type second impurity diffusion region formed in the surface of the first well away from the first impurity diffusion region and functioning as the emitter.

13. The device according to claim 12, further comprising:
a first MOS transistor comprising two n-type third impurity diffusion regions each formed in the surface of the semiconductor substrate and having the same impurity concentration as the first impurity diffusion region and a gate electrode disposed on the surface of the semiconductor substrate between the two third impurity diffusion regions via the gate insulating film; and
a second MOS transistor comprising two p-type fourth impurity diffusion regions each formed in the surface of the semiconductor substrate and having the same impurity concentration as the second impurity diffusion region and a gate electrode disposed on the surface of the semiconductor substrate between the two fourth impurity diffusion regions via the gate insulating film.

14. A semiconductor device having a protective circuit which allows a surge current to flow in order to protect main circuits, the device comprising:
a surge voltage input section;
a detecting section connected to the surge voltage input section and outputting a detection signal on detecting an applied surge voltage;
an npn-type first transistor having a base supplied with the detection signal and a collector electrically connected to the surge voltage input section;
an npn-type second transistor having a base electrically connected to an emitter of the first transistor and an collector electrically connected to the collector of the first transistor; and
a thyristor section having an input connected to the surge voltage input section, an output electrically connected to ground, and a trigger signal input connected to an emitter of the second transistor.

15. The device according to claim 14, wherein each of the first transistor and the second transistor comprises:
an n-type first well formed on a surface of a semiconductor substrate and functioning as the collector;
a p-type second well formed in a surface of the first well and functioning as the base; and
an n-type first impurity diffusion region formed in a surface of the second well and functioning as the emitter.

16. The device according to claim 15, further comprising:
a p-type second impurity diffusion region formed in the surface of the second well away from the first impurity diffusion region and having a higher impurity concentration than the second well.

17. The device according to claim 16, further comprising:
a gate electrode structure formed in the surface of the second well between the first impurity diffusion region and the second impurity diffusion region.

18. The device according to claim 17, further comprising:
a first MOS transistor comprising two n-type third impurity diffusion regions each formed in the surface of the semiconductor substrate and having a same impurity concentration as the first impurity diffusion region and a first gate electrode provided on the surface of the semiconductor substrate between the two third impurity diffusion regions via a gate insulating film; and
a second MOS transistor comprising two p-type fourth impurity diffusion regions each formed in the surface of the semiconductor substrate and having a same impurity concentration as the second impurity diffusion region and a second gate electrode provided on the surface of the semiconductor substrate between the two fourth impurity diffusion regions via a gate insulating film.

19. The device according to claim 18, wherein the gate electrode structure, the first gate electrode, and the second gate electrode are derived from a same material.

20. The device according to claim 16, further comprising an isolation film formed in the surface of the second well between the first impurity diffusion region- and the second impurity diffusion region.

21. The device according to claim 20, further comprising:
a first MOS transistor comprising two n-type third impurity diffusion regions each formed in the surface of the semiconductor substrate and having a same impurity concentration as the first impurity diffusion region and a gate electrode provided on the surface of the semiconductor substrate between the two third impurity diffusion regions via a gate insulating film; and
a second MOS transistor comprising two p-type fourth impurity diffusion regions each formed in the surface of the semiconductor substrate and having a same impurity concentration as the second impurity diffusion region and a gate electrode provided on the surface of the semiconductor substrate between the two fourth impurity diffusion regions via a gate insulating film.

22. The device according to claim 14, wherein each of the first transistor and the second transistor comprises:
a p-type first well formed in the surface of a semiconductor substrate and functioning as the base;
an n-type first impurity diffusion region formed in a surface of the first well and functioning as the collector; and
an n-type second impurity diffusion region formed in the surface of the first well away from the first impurity diffusion region and functioning as the emitter.

23. The device according to claim 22, further comprising:
a first MOS transistor comprising two n-type third impurity diffusion regions each formed in the surface of the semiconductor substrate and having a same impurity concentration as the first impurity diffusion region and a gate electrode provided on the surface of the semiconductor substrate between the two third impurity diffusion regions via a gate insulating film; and
a second MOS transistor comprising two p-type fourth impurity diffusion regions each formed in the surface of the semiconductor substrate and having a same impurity concentration as the second impurity diffusion region and a gate electrode provided on the surface of the semiconductor substrate between the two fourth impurity diffusion regions via a gate insulating film.
